(19) United States
(12) Patent Application Publication
(10) Pub. No.: US 2010/0102448 A1
(43) Pub. Date: Apr. 29, 2010

(54) SEMICONDUCTOR DEVICE AND METHOD OF FABRICATING THE SAME

(76) Inventors: Hiroshi Akahori, Kanagawa (JP); Tooru Ichikawa, Kanagawa (JP); Wakako Takeuchi, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/603,289

(22) Filed: Oct. 21, 2009

(30) Foreign Application Priority Data
Oct. 27, 2008 (JP) 2008-276056

(51) Int. Cl. H01L 23/532; H01L 21/768

(52) U.S. Cl. 257/751; 438/653; 257/E21.584; 257/E23.154

(57) ABSTRACT

A semiconductor device according to one embodiment includes: a semiconductor element formed on a semiconductor substrate; a metal wiring formed above the semiconductor element; an amorphous silicon film formed above the semiconductor element, the amorphous silicon film being insulated from the metal wiring; and a metal diffusion blocking film formed above the amorphous silicon film, the metal diffusion blocking film having a property to suppress diffusion of metal atoms in the metal wiring.

### CROSS-REFERENCE TO RELATED APPLICATIONS

This application is based upon and claims the benefit of priority from prior Japanese Patent Application No. 2008-276056, filed on Oct. 27, 2008, the entire contents of which are incorporated herein by reference.

### BACKGROUND

Copper (Cu) has been extremely used as a material of a metal wiring part with increase of layer number of a wiring structure in a semiconductor device in recent years. Copper has lower electric resistance than aluminum, and has an advantage of high resistance to electromigration. A copper wiring is usually formed by damascene method. Damascene method is a method in which wiring trenches and contact holes are formed, and a barrier metal and a copper film are buried in the wiring trenches and the contact holes, and then unnecessary parts of the barrier metal and the copper film is removed.

Here, copper atoms of a copper wiring easily diffuse into a silicon oxide film or an insulating film with low permittivity called low-k film. Copper atoms which have diffused into an insulating film may induce leak current between adjacent metal wirings. Furthermore, it is the problem that device property is degraded by diffusing of copper atoms to a semiconductor element formed on a surface of a semiconductor substrate. Therefore, a barrier metal is formed between a copper wiring and an insulating film that the copper wiring is formed in. However, the resistivity of the copper wiring increases as the thickness of the barrier metal increases because, in general, electrical resistance of materials used for a barrier metal is higher than that of copper. Thus, a wiring structure that suppresses increase of wiring resistivity and diffusion of copper atoms to semiconductor active area is needed. Note that, metallic elements in a metal wiring made of metals except copper also diffuse in an insulating film, and may cause leak current between metal wirings.

In order to solve the problem mentioned above, it is suggested, for example, in JP-A-2002-373937 that a silicon nitride film is formed in an interlayer insulating film and a insulating film that metal wirings is formed in. According to the suggestion, for example, a silicon nitride film can suppress diffusion of copper atoms to an interlayer insulating film.

Meanwhile, a silicon nitride film or a silicon oxynitride film is formed by the CVD method generally using NH₃, SiH₄ and O₂ as source gas. Nitrogen and hydrogen are generated in a decomposition process of the source gas, and also diffuse into a gate oxide film of a transistor. At that time, nitrogen and hydrogen combine with defects in the gate oxide film, and become electric charge traps, causing deterioration of transistor characteristic by NBTI (Negative Bias Temperature Instability).

### BRIEF SUMMARY

A semiconductor device according to one embodiment includes: a semiconductor element formed on a semiconductor substrate; a metal wiring formed above the semiconductor element; an amorphous silicon film formed above the semiconductor element, the amorphous silicon film being insulated from the metal wiring; and a metal diffusion blocking film formed above the amorphous silicon film, the metal diffusion blocking film having a property to suppress diffusion of metal atoms in the metal wiring.

A method of fabricating a semiconductor device according to another embodiment includes: forming a semiconductor element on a semiconductor substrate; forming a metal wiring, an amorphous silicon film insulated from the metal wiring, and a metal diffusion blocking film above the semiconductor element, the metal diffusion blocking film having a property to suppress diffusion of metal atoms in the metal wiring, the metal diffusion blocking film being above the amorphous silicon film.

### BRIEF DESCRIPTION OF THE DRAWING

FIG. 1 is a cross sectional view of a semiconductor device according to an embodiment;

FIGS. 2A to 2I are cross sectional views showing processes for fabricating the semiconductor device according to the embodiment; and

FIG. 3 shows a relationship between a thickness of an amorphous silicon film and nitrogen concentration in a silicon oxide film.

### DETAILED DESCRIPTION

### Embodiment

A semiconductor device 1 according to this embodiment has a memory cell of a NAND type flash memory as a semiconductor element. In addition, other elements such as a MOSFET or a MISFET may be used in the semiconductor element.

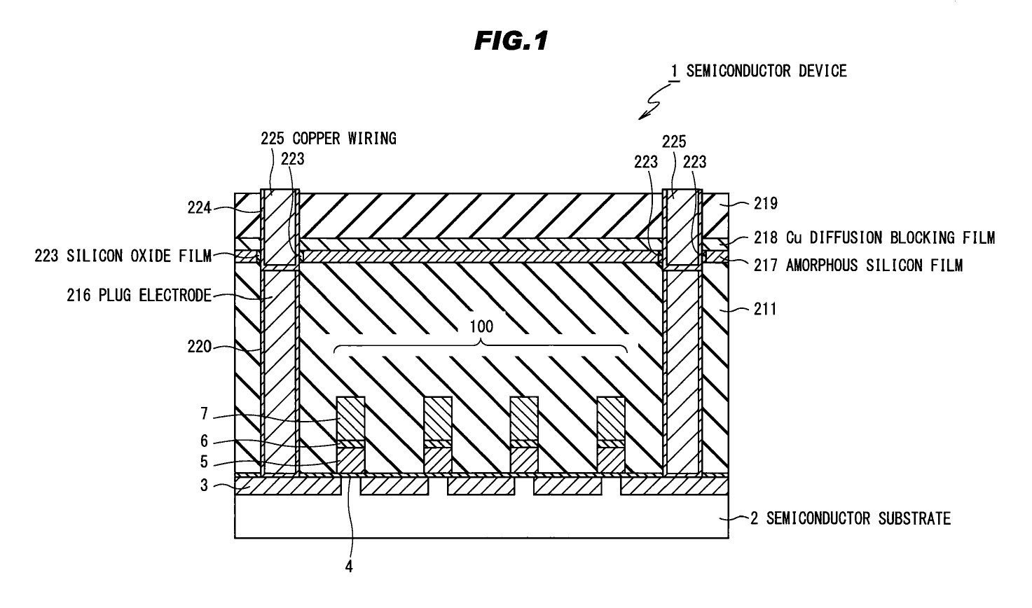

FIG. 1 is a cross sectional view of the semiconductor device 1 according to the embodiment. The semiconductor device 1 has a semiconductor element 100 formed on a semiconductor substrate 2, copper wirings 225 formed above the semiconductor element 100, plug electrodes 216 that electrically connects the copper wirings 225 to the semiconductor element 100, a silicon oxide film 211 formed on the semiconductor element 100, an amorphous silicon film 217 formed on the silicon oxide film 211, a Cu diffusion blocking film 218 formed on the amorphous silicon film 217, and an interlayer insulating film 219 formed on the Cu diffusion blocking film 218.

Surfaces of the plug electrode 216 and the copper wiring 225 are respectively covered with barrier metal 220 and 224.

An insulating film such as silicon nitride film, silicon carbide film, silicon carbonitride film or silicon oxynitride film is used for the Cu diffusion blocking film 218. The Cu diffusion blocking film 218 has a property of hardly transmitting copper atoms. Therefore, the Cu diffusion blocking film 218 can prevent diffusive transfer of copper atoms from the copper wirings 225.

The amorphous silicon film 217 has a property of hardly transmitting nitrogen and hydrogen. Therefore, the amorphous silicon film 217 can prevent transfer of nitrogen and hydrogen that are generated at formation of the Cu diffusion blocking film 218.

The silicon oxide film 223 is formed between the amorphous silicon film 217 and copper wirings 225 so as to continue into the amorphous silicon film 217. In addition, the silicon oxide film 223 is formed between the amorphous silicon film 217 and the plug electrodes 216 when a part of the plug electrodes 216 is level with the amorphous silicon film 217. Furthermore, the silicon oxide film 223 is formed between the amorphous silicon film 217 and the copper wiring 225 and between the amorphous silicon film 217 and the plug electrodes 216 when a level of an interface between the copper wiring 225 and the plug electrodes 216 is between levels of an upper surface and a lower surface of the amorphous silicon film 217.

As a result, the amorphous silicon film 217 does not contact the barrier metals 220 and 224, and is insulated from the copper wirings 225 and the plug electrodes 216.

Even if the barrier metals 220 and 224 are not formed, the amorphous silicon film 217 is insulated from the copper wirings 225 and the plug electrodes 216 because the silicon oxide film 223 is formed between a side surface of the amorphous silicon film 217 and a side surface of the copper wiring 225 facing each other.

The semiconductor element 100, which is a memory cell of a NAND type flash memory, has transistors that are connected in series via source/drain regions 3 formed in the semiconductor substrate 2. Each of the transistors has a floating gate 5 formed on the semiconductor substrate 2 via a gate oxide film 4, and a control gate 7 formed on the floating gate 5 via an inter-gate insulating film 6.

A metal wiring made of metal such as Ti—Cu alloy, Al—Si—Cu alloy or Al—Si alloy may be used instead of the copper wiring 225. The plug electrode 216 is made of, for example, conductive metal such as tungsten, titanium nitride or tungsten silicon nitride.

The wiring structure mentioned above is a single-layer wiring structure, but it may be a multi-layer wiring structure.

An example of processes for fabricating the semiconductor device 1 will be described hereinafter.

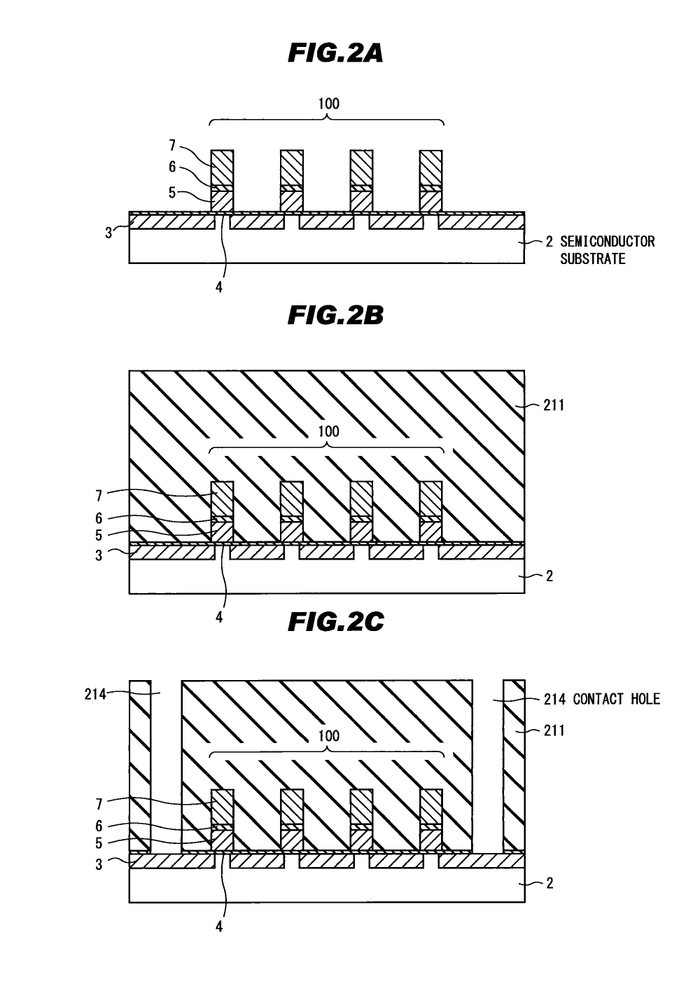

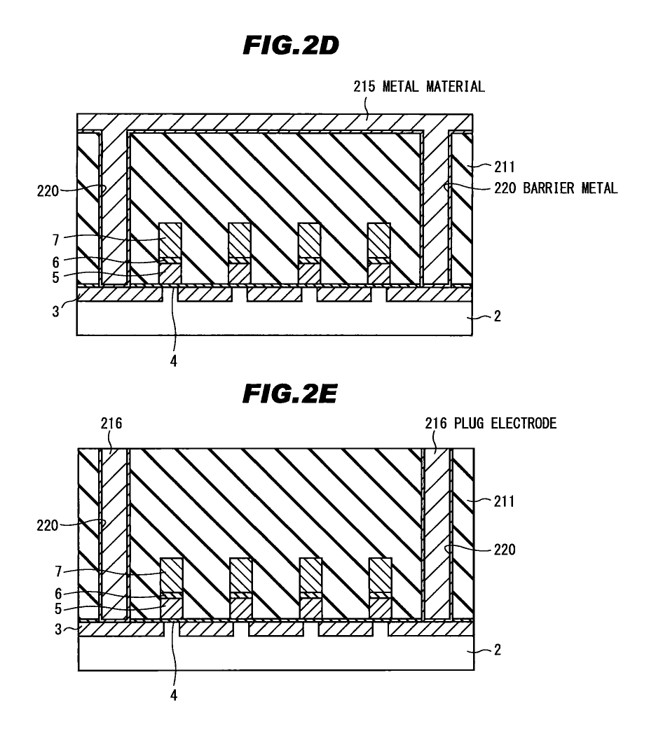

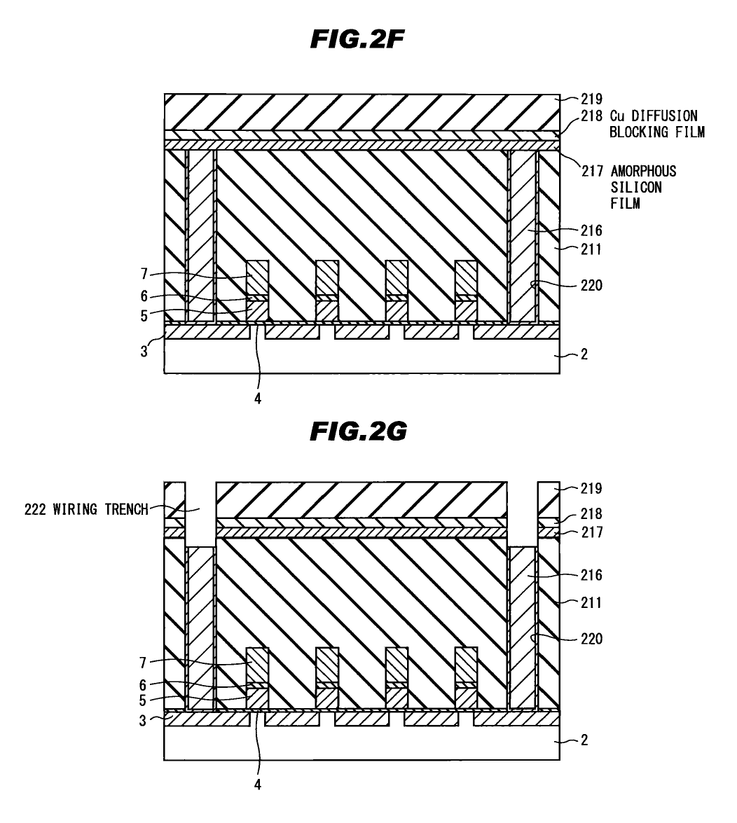

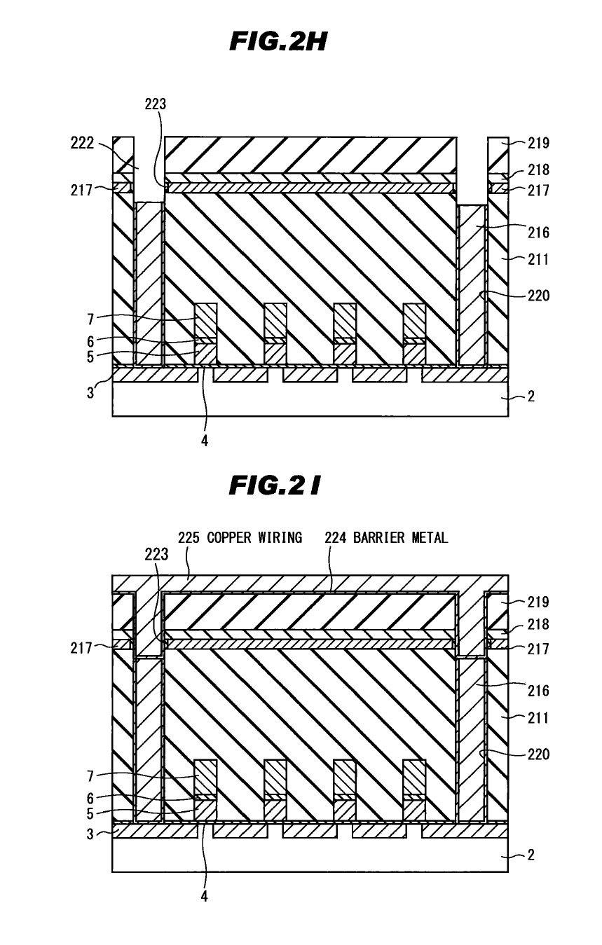

FIGS. 2A to 2I are cross sectional views showing processes for fabricating the semiconductor device 1 according to the embodiment.

FIG. 2A is a cross sectional view showing the semiconductor element 100, which is a memory cell of a NAND type flash memory, formed on the semiconductor substrate 2. The processes to form the semiconductor element 100 are like the next.

First, a first insulating film and a first semiconductor film, which will be respectively shaped to the gate oxide film 4 and the floating gate 5 in a subsequent process, are stacked. Next, trench is formed so as to penetrate the first semiconductor film and the first insulating film and reach the semiconductor substrate 2, and then an element isolation region (not shown) is formed in the trench. After that, a second insulating film and a second semiconductor film, which will be respectively shaped to the inter-gate insulating film 6 and the control gate 7 in a subsequent process, are stacked on the first semiconductor film and the element isolation region.

Here, the second semiconductor film is made of Si-based polycrystal such as polycrystalline Si. In addition, the second semiconductor film may be made of Si-based polycrystal including impurities such as P, B. The first and second insulating films are formed by thermal oxidation method, CVD (Chemical Vapor Deposition) method, LPCVD (Low-Pressure CVD) method, etc. The first and second semiconductor films are formed by the LPCVD method, etc.

The second semiconductor film, the second insulating film, the first semiconductor film and the first insulating film are patterned by photolithography method and RIE (Reactive Ion Etching) method, etc., forming the control gate 7, the inter-gate insulating film 6, the floating gate 5 and the gate oxide film 4.

In addition, after the control gate 7, the inter-gate insulating film 6, the floating gate 5 and the gate oxide film 4 are formed, conductivity type impurities are implanted by ion implantation procedure, etc., into a surface of the semiconductor substrate 2 that has been exposed by self-alignment with the obtained stacked-gate structure, and then the implanted impurities are activated by heat treatment, forming the source/drain region 3.

Next, as shown in FIG. 2B, for example, TEOS (Tetra Ethyl Ortho Silicate) is deposited by CVD method on the whole surface of the semiconductor substrate 2, on which the semiconductor element 100 is formed, forming the silicon oxide film 211. The thickness of the silicon oxide film 211 is, for example, 0.5 μm to 5 μm. It is preferable that the silicon oxide film 211 is planarized by CMP (Chemical Mechanical Polishing) method in order to retain processing accuracy of members that will be formed above the silicon oxide film 211.

Next, as shown in FIG. 2C, a photoresist is applied on the whole surface of the silicon oxide film 211, and is exposed and developed by photolithography method, forming a photoresist pattern on the silicon oxide film 211. Then, a pattern of the photoresist pattern is transferred to the silicon oxide film 211 by RIE method using the photoresist pattern as a mask, thereby forming contact holes 214. After that, the photoresist pattern is removed. The depth of the contact holes 214 reach to, for example, the control gate 7 or the source/drain region 3 of the semiconductor element 100.

Next, as shown in FIG. 2D, after the barrier metals 220 are formed over the semiconductor substrate 2 so as to cover the inner surfaces of the contact holes 214, a metal material 215 is buried in the contact holes 214 by physical film formation method such as sputtering method or chemical film formation method such as CVD method. The metal material 215 is made of, for example, conductive material such as tungsten, titanium nitride or tungsten silicon nitride.

Next, as shown in FIG. 2E, excess of the upper portions of the metal material 215 and the barrier metals 220 above the contact holes 214 and the silicon oxide film 211 is removed by planarization treatment using CMP method, thereby forming the plug electrodes 216. The metal material 215 and the barrier metals 220 are subjected to the planarization treatment under a condition in which polishing rate for the silicon oxide film 211 is sufficiently lower than that for the metal material 215. The plug electrodes 216 function as electrodes that electrically connect the source/drain region 3 and the copper wiring 225 of the semiconductor element 100. In addition, although it is not illustrated, the plug electrodes 216 may be formed at a position at which the plug electrodes 216 connect the control gate 7 and a wiring above the control gate 7.

Next, as shown in FIG. 2F, the amorphous silicon film 217 is formed on the whole region of upper surfaces of the silicon oxide film 211 and the plug electrodes 216 by CVD method. It is preferable that the amorphous silicon film 217 is formed so as to have a thickness of not less than 1 nm. Next, silicon nitride film, silicon carbide film, silicon carbonitride film or silicon oxynitride film is formed with a thickness of, for example, 10 nm to 100 nm as the Cu diffusion blocking film 218 by CVD method. Then, for example, TEOS is deposited on the Cu diffusion blocking film 218, forming the interlayer insulating film 219. The thickness of the interlayer insulating film 219 is, for example, 0.05 μm to 3 μm.

Next, as shown in FIG. 2G, wiring trenches 222 are formed. Specifically, first, a photoresist is applied on the whole surface of the interlayer insulating film 219, and is exposed and developed by photolithography method, forming a photoresist pattern on the interlayer insulating film 219. Then, a pattern of the photoresist pattern is transferred to the interlayer insulating film 219, the Cu diffusion blocking film 218 and the amorphous silicon film 217 by RIE method using the photoresist pattern as a mask, thereby forming the wiring trenches 222 that reach the plug electrodes 216. After that, the photoresist pattern is removed.

Next, as shown in FIG. 2H, side faces of the amorphous silicon film 217 exposed in the wiring trenches 222 are subjected to oxidation treatment, forming the silicon oxide film 223. At this time, the amorphous silicon film 217 is selectively subjected to the oxidation treatment by selective thermal oxidation method, etc. so that the plug electrodes 216 are not oxidized.

Here, the selective thermal oxidation method can be carried out under a condition in which oxidation reaction is dominant for silicon and reduction reaction is dominant for metal by control of a process condition such as the ratio of hydrogen and oxygen in process gas, temperature or the RF (Radio Frequency) power. The amorphous silicon film 217 can be selectively oxidized without oxidation of the plug electrode 216 by using this oxidation method.

The amorphous silicon film 217 is not exposed in inner surfaces of wiring trenches 222 because silicon oxide film 223 is formed. Therefore, the barrier metals 224 and the copper wirings 225 formed in the wiring trenches 222 do not contact with the amorphous silicon films 217.

Next, as shown in FIG. 2I, the barrier metals 224 are formed over the semiconductor substrate 2 so as to cover the inner surfaces of the wiring trenches 222 by physical film formation method such as sputtering method or chemical film formation method such as CVD method. The thickness of the barrier metal 224 is, for example, 3 nm to 50 nm. The barrier metal 224 is made of, for example, conductive material such as metal (niobium or tantalum, etc.) or alloy (tungsten, titanium nitride or tungsten silicon nitride, etc.).

Then, after the barrier metals 224 are formed, a copper material is formed over the semiconductor substrate 2 so as to embed in the wiring trenches 222 by electrolytic plating method, and then excess of the upper portions of the copper material and the barrier metals 224 above the interlayer insulating film 219 is removed by planarization treatment using CMP method, thereby forming the copper wirings 225. As a result, the semiconductor device 1 shown in FIG. 1 is obtained. Note that, the copper material and the barrier metals 224 are subjected to the planarization treatment under a condition in which polishing rate for the interlayer insulating film 219 is sufficiently lower than that for the copper material. The barrier metal 224 has functions of acceleration of growth of copper and prevention of diffusion of copper from the copper wiring 225 to circumference.

In addition, as necessary, an interlayer insulating film such as TEOS film is formed over the semiconductor substrate 2 by CVD method, and then same formation processes of plug electrodes and wirings as previously described are repeated as many times as needed, thereby forming a multi-layer wiring structure.

### Effects of the Embodiment

When copper wirings are used for a wiring structure of a semiconductor device, an insulating film such as a silicon nitride film or a silicon oxynitride film is usually formed as a Cu diffusion blocking film in order to prevent diffusion of copper atoms to a silicon oxide film (an interlayer insulating film).

When a silicon nitride film or a silicon oxynitride film is used, NH₃ gas, SiH₄ gas and O₂ gas are generally used as a source gas for CVD method. Nitrogen and hydrogen are generated in a decomposition process of the source gas, and also diffuse into a gate oxide film of a transistor. At that time, nitrogen and hydrogen combine with defects in the gate oxide film, and become electric charge traps. As a result, deterioration of transistor characteristic may be generated by NBTI (Negative Bias Temperature Instability).

However, according to the embodiment, transfer of nitrogen and hydrogen that are generated at formation of the Cu diffusion blocking film 218 to the semiconductor element 100 side is efficiently suppressed because the amorphous silicon film 217 is formed under the Cu diffusion blocking film 218 (In other words, the amorphous silicon film 217 is formed in the semiconductor element 100 side of the Cu diffusion blocking film 218).

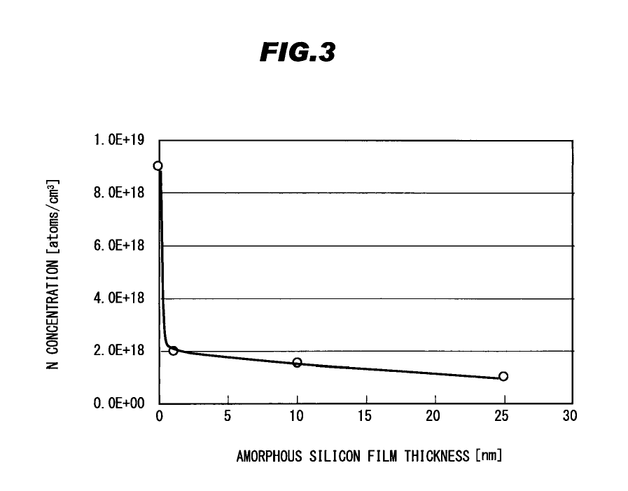

FIG. 3 shows a relationship between the thickness of the amorphous silicon film 217 and the nitrogen concentration in the silicon oxide film 211. The vertical axis shows a number of nitrogen atoms per 1 cubic centimeter. In other words, the vertical axis shows the degree of diffusion of nitrogen into the silicon oxide film 211 through the amorphous silicon film 217. The horizontal axis shows the thickness (nm) of the amorphous silicon film 217.

FIG. 3 shows the state in which nitrogen in the silicon oxide film 211 decreases as the thickness of the amorphous silicon film 217 increase. Diffusion of nitrogen can be efficiently suppressed by setting the thickness of the amorphous silicon film 217 to 1 nm or more.

In addition, since the silicon oxide film 223 is formed in the copper wiring 225 side of the amorphous silicon film 217, the amorphous silicon film 217 does not contact the barrier metals 220 and 224, and is certainly insulated from the copper wirings 225 and the plug electrodes 216. As a result, reliability of the semiconductor device 1 can be increased.

Note that, the present invention is not limited to the embodiment mentioned above. For example, although the structure in which the amorphous silicon film 217 is formed in whole region under the Cu diffusion blocking film 218, which is made of silicon nitride film, silicon carbide film, silicon carbonitride film or the silicon oxynitride film, etc., under the copper wiring 225 is shown in the embodiment mentioned above, an interlayer insulating film may be between the bottom of the Cu diffusion blocking film 218 and the amorphous silicon film 217.

In addition, the Cu diffusion blocking film 218 may be formed by a method in which the amorphous silicon film 217 is formed on the entire upper surface of a lower member and the upper portion of the amorphous silicon film 217 is nitrided by radical nitridation treatment at a temperature of 500° C. or less.

In addition, although a copper wiring structure of a bottom layer is shown in the embodiment mentioned above, the same structure as this structure can be used for copper wirings of other layer in a multi-layer wiring structure.

In addition, the present invention can be applied to dual damascene process, in which a trench for a copper wiring and a plug electrode is formed and a barrier metal and copper wiring are buried.

Furthermore, the amorphous silicon film 217 may be formed in the whole region under a film, which is made of silicon nitride film, silicon carbide film, silicon carbonitride film or the silicon oxynitride film, etc., formed to block diffusion of moisture and impurities on a top layer in a multilayered wiring structure.

Moreover, depending on types of the semiconductor element 100 or a layout of the circuit of them, the semiconductor element part 100 and the copper wiring 225 may not be connected by the plug electrode 216. Even in this case, diffusion of copper in the copper wiring 225 can be suppressed by the Cu diffusion blocking film 218, and diffusion of nitrogen and hydrogen to the semiconductor elements 100 side can be suppressed by the amorphous silicon film 217.

What is claimed is:

1. A semiconductor device, comprising:
a semiconductor element formed on a semiconductor substrate;
a metal wiring formed above the semiconductor element;
an amorphous silicon film formed above the semiconductor element, the amorphous silicon film being insulated from the metal wiring; and
a metal diffusion blocking film formed above the amorphous silicon film, the metal diffusion blocking film having a property to suppress diffusion of metal atoms in the metal wiring.

2. The semiconductor device according to claim 1, further comprising:
a plug electrode connecting the semiconductor element and the metal wiring, the plug electrode being insulated from the amorphous silicon film.

3. The semiconductor device according to claim 2, further comprising:
a silicon oxide film formed between the amorphous silicon film and the copper wiring so as to continue into the amorphous silicon film.

4. The semiconductor device according to claim 3, wherein the metal diffusion blocking film is a silicon nitride film, a silicon carbide film, a silicon carbonitride film or a silicon oxynitride film.

5. The semiconductor device according to claim 4, wherein a thickness of the amorphous silicon film is 1 nm or more.

6. The semiconductor device according to claim 5, wherein the metal wiring contains copper.

7. The semiconductor device according to claim 1, further comprising:
a silicon oxide film formed between the amorphous silicon film and the copper wiring so as to continue into the amorphous silicon film.

8. The semiconductor device according to claim 7, wherein the metal diffusion blocking film is a silicon nitride film, a silicon carbide film, a silicon carbonitride film or a silicon oxynitride film.

9. The semiconductor device according to claim 8, wherein a thickness of the amorphous silicon film is 1 nm or more.

10. A method of fabricating a semiconductor device, comprising:
forming a semiconductor element on a semiconductor substrate;
forming a metal wiring, an amorphous silicon film insulated from the metal wiring, and a metal diffusion blocking film above the semiconductor element, the metal diffusion blocking film having a property to suppress diffusion of metal atoms in the metal wiring, the metal diffusion blocking film being above the amorphous silicon film.

11. The method of fabricating a semiconductor device according to claim 10, further comprising:
forming a wiring trench in the amorphous silicon film and the metal diffusion blocking film; and
providing oxidation treatment to a surface of the amorphous silicon film exposed in the wiring trench,
wherein the metal wiring is formed in the wiring trench after the oxidation treatment.

12. The method of fabricating a semiconductor device according to claim 11, further comprising:
forming a plug electrode contacted to the semiconductor element after the formation of the semiconductor element,
wherein the wiring trench is formed so that a upper surface of the plug electrode is exposed; and
the amorphous silicon film is selectively oxidized by the oxidation treatment so that the plug electrode is not oxidized.

13. The method of fabricating a semiconductor device according to claim 12, wherein the metal diffusion blocking film is a silicon nitride film, a silicon carbide film, a silicon carbonitride film or a silicon oxynitride film.

14. The method of fabricating a semiconductor device according to claim 13, wherein the amorphous silicon film is formed so as to have a thickness of 1 nm or more.

15. The method of fabricating a semiconductor device according to claim 12, wherein the metal diffusion blocking film is formed by nitriding the amorphous silicon film.

16. The method of fabricating a semiconductor device according to claim 15, wherein a thickness of the amorphous silicon film after the formation of the metal diffusion blocking film is 1 nm or more.

17. The method of fabricating a semiconductor device according to claim 11, wherein the metal diffusion blocking film is a silicon nitride film, a silicon carbide film, a silicon carbonitride film or a silicon oxynitride film.

18. The method of fabricating a semiconductor device according to claim 11, wherein the metal diffusion blocking film is formed by nitriding the amorphous silicon film.

19. The method of fabricating a semiconductor device according to claim 10, wherein the metal diffusion blocking film is a silicon nitride film, a silicon carbide film, a silicon carbonitride film or a silicon oxynitride film.

20. The method of fabricating a semiconductor device according to claim 10, wherein the metal diffusion blocking film is formed by nitriding the amorphous silicon film.
